(19) United States
(12) Patent Application Publication
(10) Pub. No.: US 2015/0136119 A1
(43) Pub. Date: May 21, 2015

(54) METHOD FOR SHAPING A FILM OF A MATERIAL THAT HAS LOW RESISTANCE TO TRACTION, AND MIRROR COMPRISING SUCH A FILM

(71) Applicant: HELIOCLIM, MANDELIEU LA NAPOULE (FR)

(72) Inventors: Yannick Godillot, Pegomas (FR); Marie Nghiem, Mandelieu La Napoule (FR); Michael Pes, Eze (FR); Charles Daniel, Mandelieu La Napoule (FR); Yann Vitupier, Mougins (FR)

(21) Appl. No.: 14/400,795

(22) PCT Filed: May 14, 2013
(86) PCT No.: PCT/FR2013/051053

§ 371 Date: Nov. 12, 2014

(30) Foreign Application Priority Data
May 14, 2012 (FR) 1254403

(51) Int. Cl. F24J 2/10; G02B 19/00; B32B 37/14; B32B 38/00; C03B 23/03; H01L 31/054

(52) U.S. Cl. CPC F24J 2/1057; C03B 23/0305; H01L 31/0547; B32B 37/14; B32B 38/0012; G02B 19/0019; G02B 19/0023; G02B 19/0042
USPC 126/684; 156/222; 156/62.2; 156/224; 359/846

(57) ABSTRACT

A method for shaping a glass sheet having a thickness Ev by applying and adhering a layer of a first material that can be subjected to traction onto a first surface of the glass sheet. The layer has a thickness E1. Either the neutral fiber of the complex moves across into the layer of the first material, the glass being then completely under compression; or the neutral fiber moves towards the first material but remains in the glass sheet, the surface of the glass being then subjected to a level of traction lower than the failure value. The complex comprising the glass sheet coated with the first layer of material is deformed, such that it is close to the final shape and the glass is mainly under compression. A stabilizing element B is applied and adhered or attached onto the complex A and of dimensionally stabilizing the final shape.

### FIELD OF THE INVENTION

The present invention relates to a method for shaping a sheet of material that has low resistance to traction, for example glass, and a mirror comprising such a sheet.

The invention also relates to a mirror for concentrating solar energy, in particular for inclusion in a device for transforming solar energy into electrical or thermal energy, in particular by reflecting, concentrating or focusing the solar energy by means of a mirror, comprising a sheet shaped by the method, towards a collector of heat or electrical energy.

In the case of thermal use, the method described in the present invention allows a device to be realized, said device allowing a heat-transfer fluid (water, water with additive, oil or other) to be heated for various applications, for example to supply an air-conditioning device, to produce heat for industry, agri-food or other direct or indirect use of the heat thus produced.

### TECHNOLOGICAL BACKGROUND

Several ways of collecting solar energy are known. A first way consists of transforming the solar energy into electrical energy, in particular by means of photovoltaic cells.

A second way of collecting solar energy consists of transforming the solar energy into thermal energy, in particular by concentrating or focusing reflected solar energy towards a heat collector, for example by means of a mirror, parabolic or cylindrical parabolic in shape.

Shaping the mirror and, where applicable, the glass sheet that it comprises as reflector element, is a problem.

Thus, French patent no. FR2 659 957, registered on 20 Mar. 1990, is known; it describes a method, shown in FIG. 1, for bending at least one glass sheet on a frame by gravity. This method comprises:

a step 100 of stacking the glass sheet or sheets,

a step 110 of arranging on a bending frame in a horizontal position,

a step 120 of raising to the deformation temperature of the glass,

a step 130 of bending into a first shape corresponding to an approximation of the final shape, and

a step 140 of bending into the final shape.

However, during the step 120, the temperature of the mirrors is raised to the deformation temperature of the glass, i.e. close to 600° C. This method is therefore energy-intensive. In addition, the mirrors intended to collect the solar energy being generally large, it therefore appears that the method can require large-size furnaces in line with the size of the mirror. As such furnaces generally have a greater thermal inertia than the mirror to be shaped, they therefore require even more operating power, especially in steps 130 and 140 of the method.

When such glass needs to be hardened by tempering, because of the sizes of the glass sheets, for example cylindrical parabolic in shape, these tempering operations appear difficult to implement without the risk of breaking a large number of glass sheets thus curved according to the method.

This hot shaping must be carried out before the reflective coating is applied since the latter usually does not support the deformation temperatures of the glass. In addition, this step of applying the reflective coating must be performed on a non-flat shape, which requires special tools and generates significant costs.

These methods of hot shaping lead to the production of very thick reflectors (typically 4 to 30 mm) using a lot of material and energy to make them. These reflectors are therefore very heavy, which makes them unsuitable for installations off the ground, in particular on building roofs. Moreover, in the most common case where the solar radiation must go through the glass layer to be reflected, the thickness of glass leads to radiation loss by absorption, which results in a reduction of the reflectors efficiency.

Another shaping technique consists of elastically deforming, at ambient temperature, a glass sheet coated beforehand with a reflective coating, and maintaining this shape by a supporting structure having this shape.

This technique overcomes several problems mentioned in the hot shaping described above.

U.S. Pat. No. 4,238,265 “Method of manufacturing a glass parabolic-cylindrical solar collector”; WO2012/138087 “Curved laminated panel, preferably parabolic, with a mirror, and process for its manufacturing” and U.S. Pat. No. 4,124,277 “Parabolic mirror construction” are known. These inventions allow the mirror or glass sheet to be deformed without exceeding the failure limit of the glass.

In this case, the main disadvantages are:
the maximum curvature of the final reflector remains limited;
in addition, the failure limit of the glass follows a statistical distribution associated with Weibull parameters, which from an industrial point of view over a large number of parts increases the risk of breakage, even with a limited curvature; and
the bending generates tensile stresses in the surface of the glass that can favor the appearance of cracks during the shaping or that make the product fragile during its lifetime.

International application WO 02/00428 is also known. This document provides for the compression of the glass to be achieved by means of the contraction of the resin during its polymerization. This entails significant thicknesses of resin to apply the compression stress, and the impossibility of using reinforcements (fiber or other) that could restrict this contraction. Nor does this method, which “facilitates the glass sheet handling operations”, make it possible to obtain large curvatures, significantly greater than the bending failure limit of the glass (see FIG. 4).

The differing mechanical resilience of glass and ceramic materials between tensile strength and compression strength is known to the expert. The compression resistance of this type of material can be 6 to 15 times greater than their tensile strength.

### BRIEF DESCRIPTION OF THE INVENTION

The present invention aims to remedy all or part of these drawbacks.

The subject of the present invention consists of establishing a biaxial compression prestress in the glass in order to:
exceed the initial failure limit of the glass to obtain a significantly higher curvature than in the inventions described above. This makes it possible to obtain better focusing, since the increase in the curvature reduces the sensitivity to shape defects and to deformations of the reflector; and/or
improve the robustness of the reflector by installing compression prestresses as in the case of tempered glass. Increased resilience to aggressions (shocks, exterior stresses on the mirror), by obtaining similar characteristics to those of tempered glass.

To this end, according to a first aspect, the present invention envisages a method for shaping a sheet of a material that has low resistance to traction (ceramic, vitroceramic, etc.) for example a glass sheet with a thickness Ev. This sheet may comprise a reflective coating. In the rest of the description the sheet, whether coated with a reflective coating or not, is called “glass sheet”. This method comprises firstly a step of applying and adhering a layer of a first material resilient to traction onto a first surface of the glass sheet, said layer having a thickness E1. As a result, under the effect of a bending loading, the neutral fiber, in a section perpendicular to the plane of the glass sheet and to the bending axis of the complex formed by the glass sheet and the layer of the first material, is moved by more than 20% of the thickness Ev from the side of the layer of the first material relative to its initial position.

This first material, resilient to traction, may have orthotropic characteristics so as to generate biaxial compression prestresses in the glass when this complex is subjected to bending. The orientation of this orthotropic material is chosen according to the axis of curvature.

The biaxial compression prestresses in the glass may be adjusted according to
elasticity moduli of the glass and of the first material in the direction of bending and the perpendicular direction;
Poisson coefficients, in particular of the first orthotropic material;
thicknesses;
radii of curvature.

This step is followed by a step of deforming the complex comprising the glass sheet coated with the layer of the first material, into the final shape such that:
either the neutral fiber of the complex moves across into the first material. The glass sheet is therefore fully compressed;
or the neutral fiber moves towards the first material but remains in the glass sheet. The glass is therefore subjected to compression on one surface, and to a level of traction below the break value on the other surface.

In all cases, during the bending deformation of this complex (glass sheet and layer of the first material), the tensile stress in the glass sheet is cancelled out or significantly reduced. Because of differences in the glass sheet's tensile and compression mechanical performances, this allows much greater deformation of the complex than the glass sheet alone.

This complex can thus be curved until the required final shape.

This complex can be used maintained at this level of elastic deformation by an external device or finish its shaping process by the steps described below.

This step consists of applying a layer of a second material that will shape the elastically deformed complex in the required final position. This second material will be applied on the free surface of the layer of the first material opposite to the glass sheet.

Lastly, the method that is the subject of the invention comprises adhering the layer of the second material onto the layer of the first material and dimensionally stabilizing the final shape.

Thanks to these provisions, the method for shaping a glass sheet that is the subject of the present invention makes it possible simultaneously to:
produce a complex comprising a glass sheet, a layer of a first material adhering to a first surface of the glass sheet and a layer of a second material adhering to a surface of the layer of the first material opposite to the glass sheet; and
obtain said complex with improved mechanical characteristics in terms of mechanical resilience of the glass sheet comparable to those of tempered glass.

In embodiments, the method that is the subject of the invention comprises:
a step of positioning on a mold the glass sheet, coated on its first surface with the layer of the first material, a second surface of the glass sheet, opposite the first surface, being oriented in the direction of a die of the mold having a required shape for the glass sheet,
a step of pushing the glass sheet tight against the mold, wherein the glass sheet is brought into contact with the die to adopt its shape and then, during the step of adhering the layer of the second material onto the layer of the first material and of dimensional stabilization, the glass sheet is maintained in contact with the die.

According to particular features, the neutral fiber is offset such that the tensile stress in the glass sheet does not exceed a given stress level for a given radius of curvature (on the concave side of the glass).

According to particular features, the neutral fiber is in the layer of the first material.

According to particular features, the step of applying and adhering a layer of a first material onto a first surface of the glass sheet is performed by keeping the glass sheet substantially flat or with said first surface being concave.

According to particular features, the step of applying and adhering a layer of a first material onto a first surface of the glass sheet is performed by keeping the glass sheet in a shape allowing the required compression prestresses to be obtained during the following steps.

According to particular features, the layer of the first material may have orthotropic mechanical characteristics so as to generate a biaxial prestress in the glass sheet.

Thanks to these provisions, the method for shaping a glass sheet that is the subject of the present invention makes it possible to produce a substantially flat complex with modifications to its mechanical characteristics.

According to particular features, the layer of the first material is made of a composite material comprising mineral or organic fibers, oriented or not, woven or non-woven, maintained in a cured binder, for example polymer or non-organic.

According to particular features, the mineral fibers are of glass fiber type, the natural or artificial organic fibers are of aramid type and the polymer binder is of epoxy type.

According to particular features, the step of applying and adhering the layer of the first material onto a first surface of the glass sheet is performed by applying fibers impregnated with an uncured binder followed by a step of curing the binder during which the layer of the first material is maintained in contact with the glass sheet by applying pressure.

According to particular features, the step of adhering the layer of the second material onto the layer of the first material is achieved by curing the binder in contact with the glass sheet.

According to particular features, the step of pushing the glass sheet tight against the mold is performed simultaneously with a compression of the layer of the second material on the layer of the first material by utilizing a bladder placed on the layer of the second material and the realization of low pressure or partial vacuum between the bladder and the die of the mold, and/or by application of overpressure outside the bladder by an autoclave.

According to particular features, the die of the mold is flat or convex in shape so as to give the second surface of the glass sheet a flat or concave shape.

According to a second aspect, the present invention envisages a mirror comprising a glass sheet, a layer of a first material adhering to a first surface of the glass sheet and a layer of a second material adhering to a surface of the layer of the first material opposite to the glass sheet, wherein:

the glass sheet is principally subjected to compression;

the material of the layer of first material is mainly subjected to traction; and

the material of the layer of second material is subjected to compression.

According to particular features, a shape of a second surface of the glass sheet, notably opposite to the first surface, is flat or concave.

According to particular features, a shape of a second surface of the glass sheet, notably opposite to the first surface, is flat or convex.

According to particular features, said first surface of the glass sheet is coated beforehand with a reflective coating.

According to particular features, said second surface of the glass sheet is coated beforehand with a reflective coating.

According to a third aspect, the present invention envisages a device for transforming solar energy into thermal or electrical energy, in particular by reflecting, concentrating or focusing the solar energy by means of a mirror, towards a collector of heat or electrical energy. To do this, the mirror of the device that is the subject of the invention comprises a glass sheet, a layer of a first material adhering to a first surface of the glass sheet and a layer of a second material adhering to a free surface of the layer of the first material, the glass sheet being subjected to compression, the layer of the first material being subjected to traction, and the layer of the second material being subjected to compression.

### BRIEF DESCRIPTION OF THE DRAWINGS

Other advantages, aims and particular features of the present invention will become apparent from the description that will follow, made, as a non-limiting example, with reference to the drawings included in an appendix, in which:

FIG. 1 represents, in the form of a logical diagram, known steps utilized for bending glass sheets;

FIG. 2 represents, in a cross-section view, a cross-section perpendicular to a plane of the glass sheet of the mirror that is the subject of the invention;

FIG. 3 represents a partially exploded view of the mirror that is the subject of the invention, according to a realization of a prototype having performed satisfactorily;

FIG. 4 represents, in the form of a logical diagram, steps utilized in a particular embodiment of the method that is the subject of the present invention;

FIG. 5 represents, in the form of a logical diagram, steps utilized in a particular embodiment of the method that is the subject of the present invention;

FIG. 6 represents, in the form of a logical diagram, steps utilized in a particular embodiment of the method that is the subject of the present invention; and

FIG. 7 represents, in the form of a logical diagram, steps utilized in a particular embodiment of the method that is the subject of the present invention.

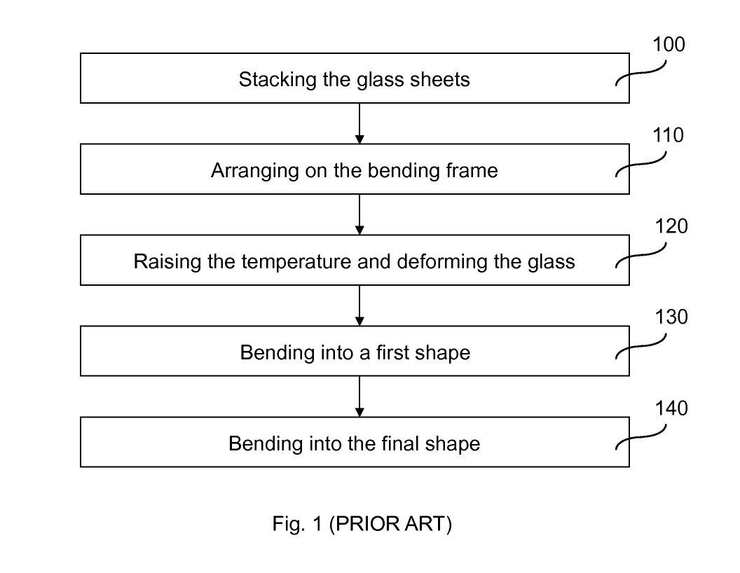

### DETAILED DESCRIPTION OF EMBODIMENTS OF THE INVENTION

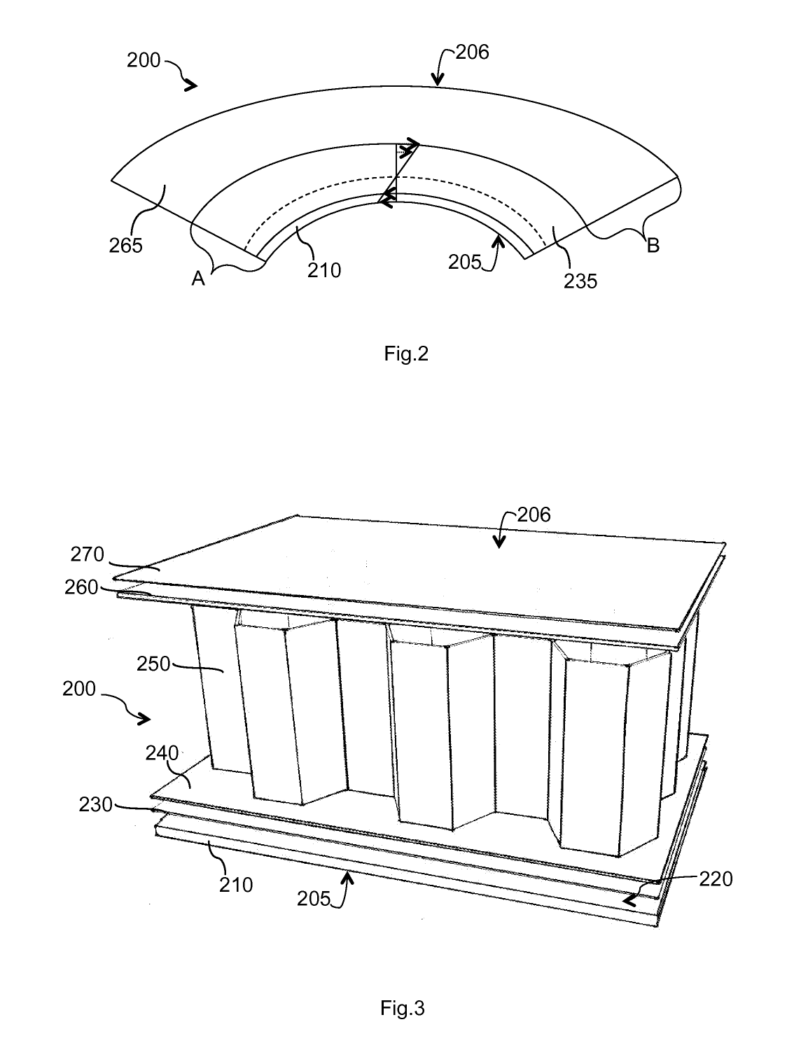

It is noted that in FIG. 2 and FIG. 3 the various components of the mirror are not shown to scale. In fact, a curvature of FIG. 2 is exaggerated in order to highlight physical phenomena and the thicknesses of the various layers are not to scale. In addition, only a small portion of the mirror of FIG. 3 is shown in order to facilitate understanding.

Thus, in FIG. 2, one can see a mirror 200 that is the subject of the invention comprising an assembly of materials in successive layers from a front surface 205 of the mirror towards a rear surface 206 of the mirror. Complex A consists of: a glass sheet, possibly coated by a reflective coating and a layer of a first material. Element B is an element allowing A to be stabilized in the required shape.

Reflective element A itself comprises a reflective glass sheet 210, on a rear surface of which a front layer of a structural material 235 is fixed.

The reflective characteristic of element A comes from properties of the glass sheet 210, which can also comprise a reflective coating on one of its two surfaces.

FIG. 2 also shows shear forces to which the element A is subjected to, the dotted line representing a neutral fiber (or neutral line) of said shear forces:
the glass sheet 210 has the characteristic of being principally subjected to compression;
the front layer 235 of structural material has the characteristic of being mainly subjected to traction;
the neutral fiber moves inside the front layer 235 of structural material or to the interface between the front layer 235 and the glass sheet 210.

In a preferred embodiment, the front layer 235 of structural material is sufficiently thick for the neutral shear fiber in the reflective element A to move into the layer 235 of structural material and for the glass sheet to be subjected to compression fully or in the greater portion of its thickness.

In embodiments, the layer 235 of structural material comprises at least one layer of a composite material, or ply, utilizing organic or mineral fibers (e.g. aramid, glass, carbon) maintained in a cured binder. For example, the material comprises at least one fabric or at least one mat of organic or mineral fibers.

The stabilization element B associated to the reflective element A has sufficient rigidity to ensure the mirrors stability of shape. To achieve this, the stabilization element B is subjected to compression such that the layer 235 of structural material is mainly subjected to traction.

Because the reflective element A is kept in compression by the front layer of structural material 235, the stabilization element B is thus itself subjected to compression.

The stabilization element B, therefore, itself comprises at least one material, having sufficient mechanical characteristics to maintain the layer 235 of structural material principally subject to traction loading.

In embodiments, element B comprises at least one structural material layer 265 of a composite material utilizing reinforcement, for example organic or mineral fibers (e.g. aramid, glass, carbon) maintained in a matrix, for example a cured binder. For example, the material comprises at least one fabric or at least one mat of organic or mineral fibers.

In embodiments, element B also comprises a core material:
of low density relative to the layers 265 and layer 235 of structural material; and
with weak mechanical characteristics compared to those of the layers 265 and layer 235 of structural material. This material may be a “honeycomb” type of alveolar material
   such that said layers and the core material form a sandwich structure. This sandwich structure can have the characteristic of being symmetrical or asymmetrical.

In embodiments, the core material is a foam. In embodiments, the core material is an alveolar material.

According to a realization of a prototype having performed satisfactorily, only a small portion of which is shown in a flat exploded view in FIG. 3, the mirror 200 comprises the assembly of materials in successive layers from the front surface 205 of the mirror towards the rear surface 206 of the mirror. It shows the glass sheet 210, coated with a reflective coating 220 on one surface of the glass sheet 210, a first glass fiber fabric 230, a first glass mat 240, an alveolar structure 250, a second glass mat 260 and a second glass fabric 270.

The above successive layers are assembled by a cured organic binder.

The glass sheet 210, coated or not with a reflective coating 220 on one surface of the glass sheet 210, the first glass fiber fabric 230 and the first glass mat 240 form the reflective element A, the front layer 235 of structural material being comprised of the first glass fiber fabric 230 and the first glass mat 240.

The alveolar structure 250, the second glass mat 260 and the second glass fabric 270 form the stabilization element B, the layer 265 of structural material being comprised of the second glass mat 260 and the second glass fabric 270.

In embodiments of prototypes having performed satisfactorily, the glass fiber fabrics 230 and 270, and the glass mats 240 and 260, have area densities of between 250 g/m² and 350 g/m². Thicknesses Ev of the glass sheet 210 are between 0.1 mm and 10 mm. Thicknesses of the honeycomb 250 are between 2 mm and 200 mm. Preferably, the honeycomb 250 is between 5 mm and 45 mm thick. More preferably, the honeycomb 250 is between 20 mm and 30 mm thick. For example, a radius of curvature less than 50 cm for a thickness greater than or equal to 1 mm. The person skilled in the art may however exceed these values depending on the sizes of mirrors.

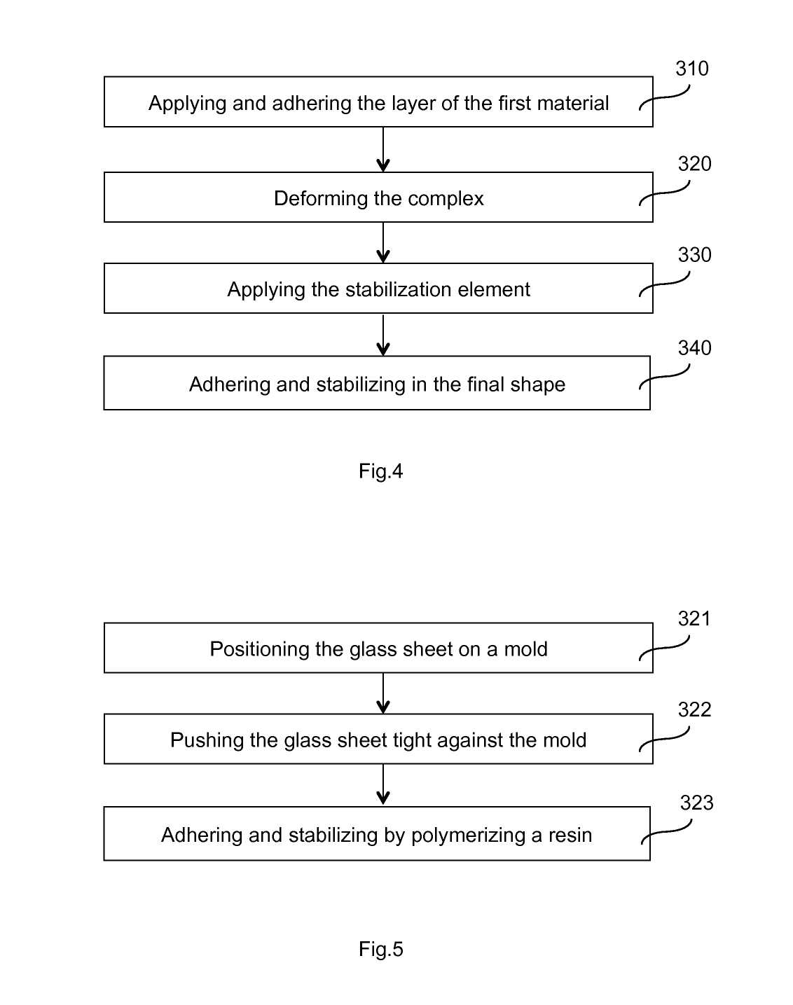

The invention also relates to a method for shaping a glass sheet, as shown in FIG. 4, an initial shape of the glass sheet being different from a final shape of said glass sheet. The method is particularly well suited to the realization of the mirror 200.

The method comprises:
a step 310 of applying and adhering a layer of a first material able to resist tensile stresses onto a first surface of the glass sheet, said layer having a thickness E1 such that, when subjected to bending, a neutral fiber, in a cross-section perpendicular to a plane of the glass sheet, of the complex formed by the glass sheet and the layer of the first material, is moved from the side of the layer of the first material, the glass sheet being in an initial shape.

In other words, during the step 310 of applying and adhering a layer of a first material onto a first surface of the glass sheet, complex A is produced.

In a particular realization, this adhesion step can consist of polymerizing a polymer resin.

In a particular realization, this step can be performed by means of a bladder, realizing a vacuum and applying pressure by means of the atmospheric pressure or an autoclave.

In a particular realization, this step can be performed on a mold having a flat, convex, concave or any other more complex shape, so as to generate the compression stresses in the glass sheet at the required level.
a step 320, which consists of deforming the complex A to a shape close to the final shape that one wishes to obtain.

In embodiments, complex A may be shaped by using a mold.

In embodiments, a vacuum device may be used to shape the complex A on the mold.
a step 330, which consists of applying the stabilization element B in order to stabilize the complex A and obtain the final shape. This second material is able to resist compression stresses on a free surface of the layer of the first material opposite to the glass sheet.

In embodiments, a set of layers of composite materials, in particular foam, honeycomb, reinforcing fabric, mat, resin or other, may be used.

In embodiments, the stabilization element B may be a supporting structure maintaining the complex A in the required position.
a step 340 of adhering the stabilizing element B onto the layer of the complex A and of dimensionally stabilizing the final shape.

In other words, during the step 340 of adhering the stabilizing element B onto the complex A and of dimensionally stabilizing the final shape, the stabilization element changes to the cured state with no external stress in the final shape, which allows it to maintain the complex in the final shape.

In embodiments, this step may be performed by applying a depressurization device, for example a bladder, drain, delamination fabric, autoclave, sealing skin or counter-mold.

In embodiments of prototypes having performed satisfactorily, the step 320 of shaping the complex comprising the glass sheet coated with the first layer of material and the layer of the second material, comprises the sub-steps shown in FIG. 5:
a step 321 of positioning on a mold the glass sheet 210, coated on its first surface with the layer of the first material, a second surface of the glass sheet, opposite the first surface, being oriented in the direction of a die of the mold having a required shape for the glass sheet;
a step 322 of pushing the glass sheet 210 tight against the mold, such that the glass sheet 210 is brought into contact with the die to adopt its shape; and
a step 323 of adhering and stabilizing the final shape by polymerizing an organic resin.

In embodiments, the complex A and the stabilization element B can be maintained in position by a device comprising a mold and a counter-mold.

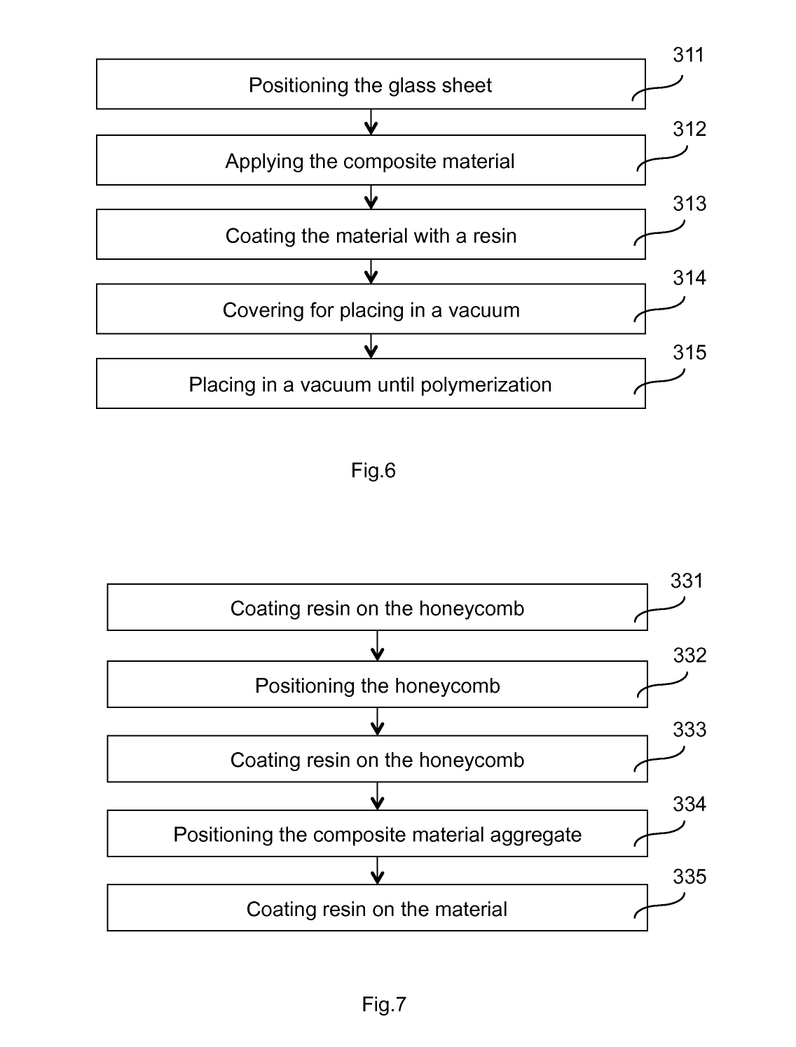

In embodiments of the method having performed satisfactorily, the step 310 of applying and adhering the layer of first material onto the first surface of the glass sheet 210 itself comprises, as shown in FIG. 6:
a step 311 of positioning the glass sheet 210 on a die of a first mold, the mold die being substantially flat, concave, convex or having a complex shape;
a step 312 of applying the composite material of the front layer 235 of structural material on the free surface of the glass sheet 210, for example by applying a dry fabric and a dry mat to be impregnated with a binder or by applying a fabric pre-impregnated with binder or a projection of binder and reinforcement according to impregnation methods known to the person skilled in the art;
a step 313 of adhering the composite material;
a step 314 of covering for placing in a vacuum; and
a step 315 of placing in a vacuum until the polymer binder is polymerized.

During the composite material application step 312, the composite material is applied such that the whole surface of the glass sheet is covered by said material. In embodiments, the composite material consists of at least one ply utilizing organic or mineral fibers (e.g. aramid, glass, carbon, etc.). In embodiments, the plies are applied pre-impregnated on the glass sheet. In embodiments, the plies are applied dry on the glass sheet and then impregnated with a polymerizable resin. Where applicable, the free surface of the glass sheet 210 is coated beforehand with the glass sheet 210 resin.

The impregnation step is known to the person skilled in the art.

The number of plies is advantageously chosen according to the required thickness of the layer 235. For example, for a glass sheet one mm thick, a fabric one mm thick and a mat 0.5 mm thick allows its realization.

The step 311 of positioning the sheet, coated on its first surface with the layer of the first material, on the mold is performed in particular such that said second surface of the glass sheet, opposite to the first surface, is oriented in the direction of said die of the mold. The die of the mold is flat or convex in shape such that said second surface of the glass sheet has a flat or concave shape.

In one preferred realization, the stabilization element B comprises a honeycomb type of alveolar structure, at least one aggregate utilizing organic or mineral fibers (e.g. aramid, glass, carbon, etc.), said aggregate being woven or not.

Thus, in one preferred realization, step 330 of applying and step 340 of adhering the stabilization element B onto the complex A themselves comprise, as shown in FIG. 7:
a step 331 of coating resin on the honeycomb;
a step 332 of positioning the honeycomb on a free surface of the layer of the first material of the reflective element A, a coated surface of the honeycomb being positioned in contact with said free surface of the first material layer;
a step 333 of coating resin on the honeycomb, in particular on a second surface of said honeycomb;
a step 334 of positioning the composite material aggregate on the honeycomb; and
a step 335 of coating with resin the composite material aggregate.

Steps 332, 333 and 334 construct the stabilization element B.

1-18. (canceled)

19. Method for shaping a sheet of a material that has low resistance to traction and having a thickness Ev, comprising the steps of:
applying and adhering onto a first surface of the sheet a layer of a first material withstanding higher tensile stresses than those of said sheet of material, said layer having a thickness E1 such that, when this complex is subjected to bending, the neutral fiber is moved by more than 20% of the sheet's thickness Ev;
elastically deforming the complex comprising the sheet coated with the first layer of material into the final shape, such that the sheet is principally subjected to compression relative to the initial shape because of the neutral fiber having moved;
applying a layer of a second material, resistant to compression stresses, on a free surface of the layer of the first material opposite to the sheet, the layer of the second material adopting a final shape of said surface of the layer of first material, the layer of second material shaping the complex into the final shape; and
adhering the layer of the second material onto the layer of the first material and dimensionally stabilizing the final shape.

20. Method according to claim 19, wherein elastically deforming the complex comprises the steps of:
positioning the sheet on a mold having a required shape for the sheet, the sheet being coated on its first surface with the layer of the first material, a second surface of the sheet, opposite the first surface, being oriented in the direction of a die of the mold; and
pushing the sheet tight against the mold, wherein the sheet is brought into contact with the die to adopt its shape, the sheet being kept pushed tight against the mold continues during the application and adherence of the layer of the second material onto the layer of the first material and dimensional stabilization.

21. Method according to claim 20, wherein pushing the sheet tight against the mold is performed simultaneously with a compression of the layer of the second material on the layer of the first material by utilizing a bladder placed on the layer of the second material and the realization of low pressure or partial vacuum between the bladder and the die of the mold, and/or by application of overpressure outside the bladder by an autoclave.

22. Method according to claim 19, wherein applying and adhering a layer of a first material onto a first surface of the sheet is performed by keeping the sheet substantially flat or with said first surface being concave.

23. Method according to claim 19, wherein, during elastically deforming the complex, the neutral fiber moves across into the layer of the first material, the material of the sheet is then fully compressed.

24. Method according to claim 19, wherein the layer of the first material has orthotropic mechanical characteristics generating a biaxial prestress in the sheet.

25. Method according to claim 19, wherein the layer of the first material is made of a composite material comprising mineral or organic fibers, oriented or not, woven or non-woven, maintained in a cured binder, for example polymer or non-organic.

26. Method according to claim 19, wherein applying and adhering the layer of the first material onto the first surface of the sheet is performed by applying fibers impregnated with an uncured binder followed by curing the binder during which the layer of the first material is maintained in contact with the sheet by applying pressure.

27. Method according to claim 19, wherein the layer of the first material is made of glass-fiber-type mineral fibers, or aramid-type natural or artificial organic fibers, and an epoxy-type polymer binder.

28. Method according to claim 19, wherein adhering the layer of the second material onto the layer of the first material and dimensionally stabilizing the final shape is performed by curing a binder between the layer of second material and the layer of first material.

29. Method according to claim 19, wherein the layer of the second material is made of a composite material comprising mineral or organic fibers, oriented or not, woven or non-woven, in a cured binder.

30. Method according to claim 29, wherein adhering the layer of the second material onto the layer of the first material is achieved by curing the compressed cured binder in contact with the layer of the first material.

31. Method according to claim 19, wherein the die of the mold is convex so as to give the second surface of the sheet a concave shape.

32. Mirror comprising a sheet, a layer of a first material adhering to a first surface of the sheet and a layer of a second material adhering to a surface of the layer of the first material opposite to the sheet, wherein:
a constitutive material of the sheet is principally subjected to compression;
the material of the layer of first material is mainly subjected to traction; and
the material of the layer of second material is subjected to compression.

33. Mirror according to claim 32, wherein a shape of a second surface of the sheet, opposite to the first surface, is flat or concave.

34. Mirror according to claim 32, wherein said first surface of the sheet is coated with a reflective coating.

35. Mirror according to claim 32, wherein said second surface of the sheet is coated with a reflective coating.

36. Device for transforming solar energy into thermal or electrical energy, by reflecting, concentrating or focusing the solar energy by a mirror, towards a collector of heat or electrical energy, wherein the mirror comprises a sheet, a layer of a first material adhering to a first surface of the sheet and a layer of a second material adhering to a surface of the layer of the first material opposite to the sheet, a constitutive material of the sheet being principally subjected to compression, the material of the layer of first material being mainly subjected to traction, and the material of the layer of second material being subjected to compression.
